(19) United States
(12) Patent Application Publication
(10) Pub. No.: US 2026/0206334 A1
(43) Pub. Date: Jul. 16, 2026

(54) MWIR BARRIER PHOTODETECTOR IN WHICH THE ABSORBING ZONE COMPRISES A STACK OF A BULK PART AND A SUPERLATTICE

(71) Applicants: COMMISSARIAT A L'ENERGIE ATOMIQUE ET AUX ENERGIES ALTERNATIVES, Paris (FR); LYNRED, Palaiseau (FR)

(72) Inventors: Olivier GRAVRAND, Grenoble Cedex 09 (FR); Nicolas PERE LAPERNE, Veurey-Voroize (FR)

(73) Assignees: COMMISSARIAT A L'ENERGIE ATOMIQUE ET AUX ENERGIES ALTERNATIVES, Paris (FR); LYNRED, Palaiseau (FR)

(21) Appl. No.: 19/134,953

(22) PCT Filed: Dec. 1, 2023
(86) PCT No.: PCT/FR2023/051896

§ 371 Date: Jun. 2, 2025

(30) Foreign Application Priority Data
Dec. 5, 2022 (FR) FR2212750

(51) Int. Cl. H10F 30/22; H10F 30/21; H10F 77/124; H10F 77/14; H10F 77/20

(52) U.S. Cl. CPC H10F 30/22; H10F 30/288; H10F 77/1248; H10F 77/1468; H10F 77/206

(57) ABSTRACT

An MWIR barrier photodetector, configured to detect a light radiation of interest having a central wavelength between 3 and 5 μm, includes a semiconductor barrier structure, produced based on III-Sb, resting on a support substrate produced based on III-Sb, and formed of an absorbing zone; a barrier layer; and a contact layer. The absorbing zone is formed of a two-part stack having a first absorbing part, doped according to a first conductivity type, made of a bulk material based on InAsSb, located on the support substrate side; and a second absorbing part, doped according to the first conductivity type, and formed of a superlattice, located between the first absorbing part and the barrier layer.

### TECHNICAL FIELD

The field of the invention is that of MWIR photodetectors comprising a semiconductor barrier structure and produced based on III-Sb.

### PRIOR ART

In the field of infrared detection, there are many developments to obtain higher-performance photodetectors, adapted to detect in mid-wave infrared (MWIR), i.e. in the spectral band ranging from about 3 to 5 μm. It may thus be a matter of being able to use such photodetectors at operating temperatures higher than usual cryogenic temperatures, for example around 120 to 170K. Such photodetectors are referred to as MWIR HOT photodetectors, for High Operating Temperature.

MWIR photodetectors may be barrier photodetectors (or bariodes, from barrier diode) of the XBn-or XBp-type, i.e. they then comprise a semiconductor structure formed of a stack of a contact layer denoted by X (n-doped or p-doped), a barrier layer denoted by B, and an absorbing zone doped n-type or p-type depending on the type of the bariode. The barrier is referred to as unipolar insofar as it blocks charge carriers of one conductivity type but allows the movement of charge carriers of the other conductivity type. Thus, in the case of an XBn bariode, the barrier layer blocks majority electrons but allows photogenerated holes in the absorbing zone to move to the contact layer. A description of such barrier MWIR photodetectors may be found, in particular, in the publication by Martyniuk et al. entitled Barrier infrared detectors, Opto-Electron. Rev., 22, no. 2, 2014. Reference may also be made to document U.S. Pat. No. 7,795,640 B2.

As a general rule, barrier photodetectors have the advantage that the SRH (Shockley-Read-Hall) recombination current contributes only weakly to the dark current, compared to its contribution in the case of pn junction photodiodes. Indeed, in such pn junction photodiodes, the SRH current contribution can be high in the space charge zone insofar as the band gap energy of the semiconductor compounds usually used for infrared detection is low. On the other hand, in a barrier photodetector, the electric field zone is confined in the large-gap barrier layer, and plays the same role as the space charge zone: blocking majority carriers while allowing photogenerated minority carriers through. The GR (generation-recombination) current contribution to dark current is then substantially reduced. Moreover, so as not to impede the photocurrent, the barrier layer has a small valence band offset (in the case of XBn-type bariodes).

Barrier photodetectors may notably be made from III-V compounds based on antimonide (Sb), which notably allow, in the case of XBn-type photodetectors, to obtain a very small valence band offset. The absorbing zone is then generally produced by epitaxy from a substrate based on III-Sb, for example made of GaSb. It can be made of a so-called bulk material, for example of InAsSb, or can be produced in the form of a superlattice, for example a type-2 superlattice (T2SL).

Superlattices and bulk materials are distinguished from each other particularly by the transport properties of charge carriers, and in particular minority carriers, in the material considered. In an unconstrained or lattice-matched bulk material, the transport of minority carriers is isotropic: they can move in the three spatial dimensions without constraints. On the other hand, in a superlattice, the transport of these minority carriers is anisotropic: lateral transport in the plane of the layers, i.e. in an orthogonal plane to the growth axis, is greater (and similar to transport in a bulk material) than vertical transport along the axis orthogonal to the plane of the layers, due to the presence of the potential barriers of the superlattice.

These two technological categories (bulk materials and superlattices) have different absorption properties in the MWIR spectral band, and are used differently according to whether detection is sought in only a part or in the entire MWIR spectral band.

Indeed, let us recall that the MWIR spectral band, which corresponds to an atmospheric transmission window, is divided into two sub-bands located on either side of the CO₂ absorption wavelength at 4.2 μm: a ‘blue band’ for wavelengths below 4.2 μm, and a ‘red band’ for wavelengths above 4.2 μm.

In addition, MWIR barrier photodetectors in which the absorbing zone is made of a bulk material made of InAsSb (lattice-matched with a GaSb substrate) are used to detect light radiation essentially in the mid-wave infrared ‘blue band’, due to the cut-off wavelength of InAsSb at 4.1 μm at 150K. Moreover, InSb is not produced from a GaSb substrate. Furthermore, although it has a higher cut-off wavelength (5.5 μm at 77K), increasing the operating temperature results in dark current degradation linked with the offset of InSb gap at high temperature.

Moreover, infrared photodetectors in which the absorbing zone is formed of a superlattice can absorb light radiation in the entire MWIR spectral band, i.e. both in the ‘blue band’ and in the ‘red band’, while maintaining lattice matching with the GaSb substrate. However, besides the difficulties of producing such a superlattice absorbing layer, increasing the operating temperature also results in dark current degradation. Moreover, anisotropic transport of charge carriers results in a low quantum efficiency and, in the case of a photodetector array, degrades the modulation transfer function (MTF).

### DISCLOSURE OF THE INVENTION

The aim of the invention is that of at least partially remedying the drawbacks of the prior art, and more particularly of providing an MWIR barrier photodetector, adapted to detect a light radiation over the entire MWIR spectral band, and having improved performances at a nominal operating temperature, or nominal performances but at a higher operating temperature.

For this purpose, the invention relates to an MWIR barrier photodetector, adapted to detect a light radiation of interest having a central wavelength between 3 and 5 μm. The central wavelength can be any wavelength located in this spectral band. The photodetector comprises a semiconductor barrier structure, produced based on III-Sb, resting on a support substrate produced based on III-Sb, and formed of: an absorbing zone, adapted to absorb the light radiation of interest; a barrier layer; and a contact layer.

The absorbing zone is formed of a two-part stack: a first absorbing part, doped according to a first conductivity type, made of a bulk material based on InAsSb, located on the support substrate side; and a second absorbing part, doped according to the first conductivity type, and formed of a superlattice, located between the first absorbing part and the barrier layer.

Some preferred, yet non-limiting, aspects of this MWIR photodetector are as follows.

The photodetector can comprise a detection pixel array, the first absorbing part being a continuous layer common to each detection pixel.

The contact layer can be crosslinked and formed of a plurality of portions distinct from each other. The barrier layer can be crosslinked and formed of a plurality of portions distinct from each other, and the second absorbing part can be crosslinked and formed of a plurality of portions distinct from each other, each detection pixel being formed of a mesa resting on the first absorbing part, each mesa being formed by a portion of the crosslinked contact layer, a portion of the crosslinked barrier layer, and a portion of the second crosslinked absorbing part.

Alternatively, the contact layer can be crosslinked and formed of a plurality of portions distinct from each other, each detection pixel being formed of a portion of the contact layer, the second absorbing part being a continuous layer common to each detection pixel.

The photodetector can comprise an intermediate layer located between and in contact with the first absorbing part and the second absorbing part, the intermediate layer being a continuous layer common to each detection pixel.

The first absorbing part can be produced based on InAsSb latticed-matched with the support substrate.

The second absorbing part can be produced based on InAs/InAsSb, InAs/AlSb or InAs/GaSb.

The first absorbing part can have a thickness greater than that of the second absorbing part.

The first absorbing part can have a thickness at least equal to half that of the absorbing zone

The semiconductor barrier structure can be XBn-type, the valence band of the second absorbing part having a greater energy than that of the valence band of the first absorbing part. Alternatively, the semiconductor barrier structure can be XBp-type, the conduction band of the second absorbing part having a lower energy than that of the conduction band of the first absorbing part.

### BRIEF DESCRIPTION OF THE DRAWINGS

Other aspects, aims, advantages and features of the invention will become apparent upon reading the following detailed description of preferred embodiments thereof, provided as a non-limiting example with reference to the appended drawings wherein:

FIG. 1A is a schematic and partial cross-sectional view of an MWIR barrier device according to one embodiment;

FIG. 1B illustrates an energy band diagram of the MWIR photodetector of FIG. 1A;

FIG. 2A is a schematic and partial cross-sectional view of an MWIR barrier photodetector array according to one embodiment, the pixelation of which has a shallow-etch configuration;

FIG. 2B is a schematic and partial cross-sectional view of an MWIR barrier photodetector array according to another embodiment, the pixelation of which has an intermediate configuration between the shallow-etch configuration and the deep-etch configuration.

### DETAILED DISCLOSURE OF PARTICULAR EMBODIMENTS

In the figures and in the following description, the same reference numerals represent identical or similar elements. In addition, the various elements are not shown to scale to ensure that the figures are clear. Moreover, the various embodiments and variants are not mutually exclusive and may be combined. Unless stated otherwise, the terms “substantially”, “about”, “in the order of” mean within a 10% margin, and preferably within a 5% margin. Moreover, the terms “between . . . and . . . ” and equivalents mean that the bounds are included, unless stated otherwise.

The invention relates to an infrared barrier photodetector (bariode) adapted to detect a light radiation in the entire mid-wave infrared range (MWIR), i.e. between about 3 and 5 μm. The photodetector is therefore adapted to detect an infrared radiation in the ‘blue band’(about 3-4.2 μm) as well as in the ‘red band’(about 4.2-5 μm).

Compared with a conventional MWIR barrier photodetector in which the absorbing zone would be formed of a single superlattice (conventional MWIR T2SL bariode), the MWIR photodetector according to the invention has improved performances at the nominal operating temperature of the conventional bariode, or has similar performances but at a higher operating temperature, for example 5 to 10K higher.

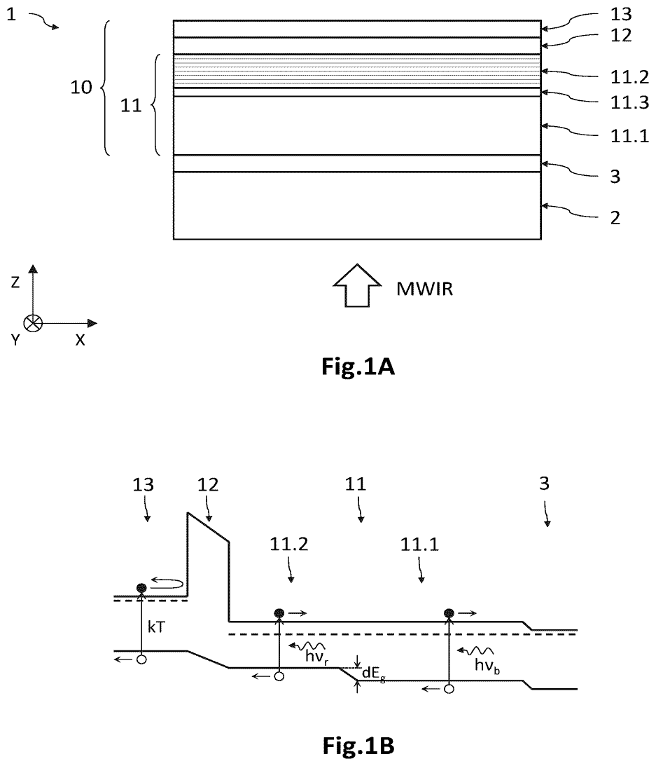

FIG. 1A is a schematic and partial cross-sectional view of a barrier photodetector 1 adapted to detect a light radiation in the entire mid-wave infrared (MWIR) spectral range. In this example, the semiconductor barrier structure 10 is nBn type-but it can also be pBn-type, or even XBp-type (nBp or pBp).

Here and hereinafter in the description, an orthogonal three-dimensional direct reference frame XYZ is defined, where the axes X and Y form a plane parallel with the plane of the layers of the semiconductor barrier structure 10, and where the axis Z is oriented along the direction of growth of the layers.

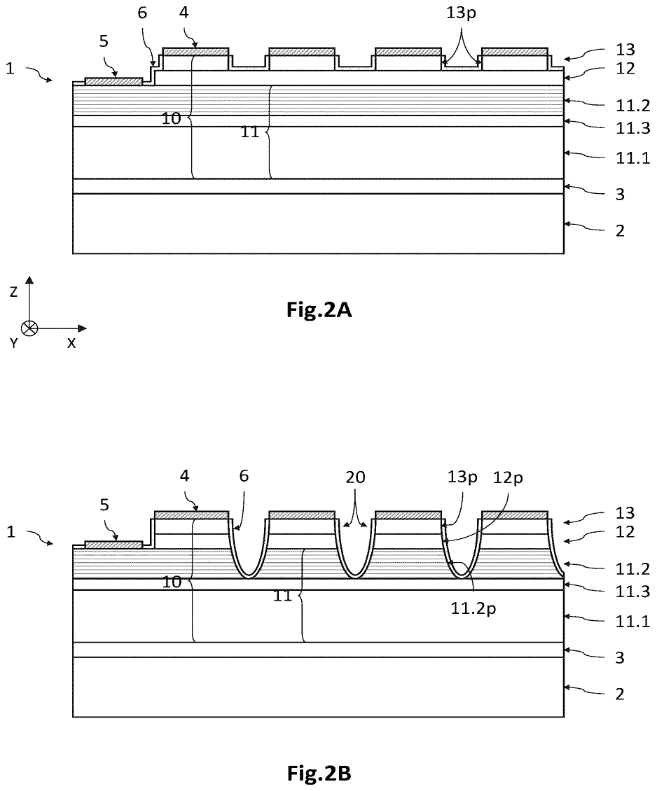

As a general rule, the photodetector 1 comprises a semiconductor barrier structure 10, produced by epitaxy from a support substrate 2, this semiconductor structure 10 being formed of a stack of an absorbing zone 11, a barrier layer 12, and a contact layer 13. Electrodes 4, 5 (see FIG. 2A) are also present to apply an electric potential difference to the semiconductor structure 10 and collect the photocurrent.

The support substrate 2 is made of an at least partially transparent material in the MWIR spectral band, insofar as the light radiation is here incident on the face opposite the semiconductor barrier structure 10. It also forms a growth substrate from which the semiconductor barrier structure 10 is produced by epitaxy. It is then made of a crystalline material based on III-Sb, and is made here of GaSb.

A lower layer 3 can be present between the support substrate 2 and the absorbing zone 11 of the semiconductor barrier structure 10. It can be made of the same crystalline material as that of the first absorbing part 11.1, for example of bulk InAs_{0.9}Sb_{0.1}. It can be overdoped, here n-type, to ensure a low series resistance between the electrodes 4 and 5, in particular in the case of a large pixel array where the electrode 5 would be located at the periphery of the sensitive pixels. The doping level can for example be greater than that of the first absorbing part 11.1, for example equal to 10¹⁷cm⁻³. The thickness can be between 0.1 and 1 μm, for example equal to 0.5 μm.

The absorbing zone 11 is the zone where the MWIR incident light radiation is absorbed. It is formed of a stack of a first absorbing part 11.1 made of a bulk crystalline semiconductor material based on III-Sb, and a second absorbing part 11.2 formed of a superlattice. It extends between the support substrate 2 (and here is in contact with the lower layer 3) and the barrier layer 12. It has a thickness adapted to ensure the absorption of incident light radiation in the entire MWIR range. The thickness can then be between 2 and 8 μm, for example equal to 5 μm.

The first absorbing part 11.1, referred to as bulk, is located between the support substrate 2 and the second SL absorbing part 11.2. It is made of a bulk crystalline semiconductor compound based on III-Sb, for example here of InAsSb. It is therefore adapted to absorb light radiation mainly in the MWIR ‘blue band’.

The first absorbing part 11.1 is referred to as bulk, insofar as it is made of a semiconductor compound which is itself bulk, i.e. a compound in which the chemical composition (the atomic proportion x of antimony Sb, in this case InA₁₋ₓSbₓ) is homogeneous or varies along the growth axis Z, without for all that forming a system of coupled multiple quantum wells.

Thus, the chemical composition (atomic proportion x of antimony) of the bulk semiconductor compound InAs₁₋ₓSbₓ can be homogeneous in the entire volume considered, here in that of the first absorbing part 11.1. An affine variation of the chemical composition (and therefore of the band gap energy) over all or part of the thickness of the first absorbing part 11.1 can also be envisaged.

Moreover, it is known that a bulk semiconductor compound InAs₁₋ₓSbₓ can also be a digital alloy, i.e. a compound formed from an alternation of thin layers of InAsSb and InAs, such that the resulting compound InAs₁₋ₓSbₓ behaves like the average chemical composition of the layers and not like a superlattice (no development of discrete levels in the quantum wells formed). For this purpose, the thin layers of at least one of the materials (preferably the layers of InAsSb) have a maximum thickness less than the spatial extent of the wave function of the electron, for example equal at most to 4 monolayers, so as to prevent quantum well coupling.

The bulk semiconductor compound is lattice-matched with the support substrate 2, and is here InAs_{0.9}Sb_{0.1} with an atomic proportion of antimony Sb in the order of 10%. In other words, the lattice parameter of the first absorbing part 11.1 is substantially equal to that of the support substrate 2. It is here in contact with the lower layer 3 insofar as it has grown epitaxially from this layer.

Moreover, the bulk semiconductor compound is doped according to a conductivity type dependent on the type of semiconductor barrier structure 10. In this example where it is nBn-type, the bulk semiconductor compound is n-doped. The doping level can be between 10¹⁵cm⁻³ and 5×10¹⁶cm⁻³, and is here equal to about 10¹⁵cm⁻³. It can be constant in the volume of the first bulk absorbing part 11.1. Alternatively, to orient the minority holes in the direction of the second SL absorbing part 11.2, the doping can vary along the direction +Z, and for example go from 5×10¹⁶cm⁻³ to 10¹⁵cm⁻³.

The first bulk absorbing part 11.1 has a thickness preferably at least equal to half the thickness of the absorbing zone 11. It can be between 1 and 4 μm, for example equal to about 3 μm in this example where the absorbing zone 11 has a thickness of about 5 μm. It is preferably greater than the thickness of the second SL absorbing part 11.2.

The absorbing zone 11 can comprise an intermediate layer 11.3, located between and in contact with the first bulk absorbing part 11.1 and the second SL absorbing part 11.2. It can make it possible to smooth any potential barrier developing at the interface between the two parts 11.1 and 11.2 capable of disrupting the transport of minority carriers to the contact layer 13 as well as majority carrier conduction. It can also improve the transport of photogenerated minority holes from the first bulk absorbing part 11.1 in the direction of the contact layer 13 by this smoothing of a potential barrier capable of developing. For this purpose, the intermediate layer 11.3 can be produced based on III-Sb, for example made of InAsGaSb, here n-doped (the absorbing zone 11 being n-type here) and having a thickness for example equal to 0.5 μm.

The second absorbing part 11.2, referred to as SL for superlattice, is located between the first absorbing part 11.1 and the barrier layer 12. It is formed of a superlattice based on III-Sb, here preferably a type II superlattice. It is therefore adapted to absorb light radiation in the MWIR blue band as well as the red band. Given that the incident light radiation belonging to the blue band is mainly absorbed in the first bulk absorbing part 11.1, the second SL absorbing part 11.2 carries out absorption essentially in the red band.

As indicated above, a superlattice is a periodic stack of thin layers (in the order of a few nanometers) of different semiconductor compounds. This stack forms a system of coupled multiple quantum wells. It can be made of InAs/GaSb or of InAs/AlSb, or even of InAs/InAsSb, inter alia, the doping of which is here n-type insofar as the semiconductor barrier structure 10 is here XBn type. The materials of the superlattice can be n-doped, for example with a doping level of the same order of magnitude as that of the first bulk absorbing part 11.1. Thus, the absorbing zone 11 has the same conductivity type in its entire volume, here n-type.

The second SL absorbing part 11.2 has a total thickness preferably at most equal to half that of the absorbing zone 11. It can be between 1 and 4 μm, and is for example equal to about 1.5 μm in this example where the absorbing zone has a thickness of about 5 μm. Its thickness is less than the diffusion length of the photogenerated minority carriers. Preferably, it is less than that of the first bulk absorbing part 11.1 so as to improve the performances of the photodetector 1 in terms of dark current. However, a thickness substantially equal to that of the first bulk absorbing part 11.1 makes it possible to optimize the MTF.

Preferably, the second SL absorbing part 11.2 has a band structure having, as illustrated in FIG. 1B, a conduction band alignment with that of the first bulk absorbing part 11.1, but a slight offset dE_{g} of the valence band (the valence band energy of the part 11.2 being greater than that of the part 11.1), thus improving the transport of minority holes in the direction of the contact layer 13. Indeed, the minority holes generated in the second SL absorbing part 11.2 will not diffuse in the first bulk absorbing part 11.1, thus improving the MTF of the photodetector 1. This offset dE_{g} is obtained by the choice of materials and the period of the thin layers of the SL part 11.2, but also by adjusting the doping levels of the bulk part 11.1 and the SL part 11.2. Note that, in the case of an XBp-type bariode, the offset dE_{g} is that of the conduction band (minority electrons). Also, the conduction band energy of the part 11.2 is less than that of the part 11.1.

The barrier layer 12 is located between the absorbing zone 11 and the contact layer 13, and is here in contact with the second SL absorbing part 11.2. As the semiconductor barrier structure 10 is here XBn type, the barrier layer 12 has a substantial conduction band offset and a small valence band offset, and thus makes it possible to block the transport of majority electrons while allowing that of photogenerated minority holes in the direction of the contact layer 13.

It is made of a crystalline semiconductor material based on III-Sb having a greater gap than those of the absorbing zone 11. By way of example, the barrier layer 12 can be produced based on InAIAsSb (here InAlAsSb). The material can here be n-doped, for example at a doping level equal to about 10¹⁶cm⁻³. The thickness can be between 0.05 and 0.5 μm, for example equal to 0.1 μm.

The contact layer 13 is located in contact with the barrier layer 12. It is made of a material based on III-Sb, for example made of InAsSb, n-doped in the case here of an nBn-type semiconductor barrier structure 10. The doping level can be between 10¹⁵cm⁻³ and 10¹⁸cm⁻³, and be for example in the order of 10¹⁷cm⁻³. The thickness can be between 0.05 and 1 μm, for example equal to 0.5 μm.

At least a first electrode 4 is located in contact with the contact layer 13, and makes it possible to apply an electric potential to the semiconductor barrier structure 10 and to collect the photocurrent. At least a second electrode 5 is located in contact with the semiconductor barrier structure 10 to apply a different electric potential to it. The second electrode 5 can be in contact with the support substrate 2, the lower layer 3, the first bulk absorbing part 11.1, or even the second SL absorbing part 11.2 (as illustrated in FIG. 2A and FIG. 2B).

Thus, as shown in FIG. 1B which illustrates an example of an energy band diagram of the photodetector 1 according to one embodiment of the invention, the incident light radiation belonging to the MWIR blue band is mainly absorbed in the first bulk absorbing part 11.1. The ‘blue’ photogenerated holes will then diffuse to the contact layer 13. Furthermore, the incident light radiation belonging to the MWIR red band is mainly absorbed in the second SL absorbing part 11.2, and the ‘red’ photogenerated holes will also diffuse to the contact layer 13. On the other hand, the barrier layer 12 will block the transport of majority electrons, and especially limit the contribution of majority carriers to dark current.

Thus, in that the absorbing zone 11 is formed of a first bulk absorbing part 11.1 and a second SL absorbing part 11.2, the photodetector 1 is capable of absorbing the incident light radiation in the entire MWIR spectral range, and has either improved performances at the nominal operating temperature of a conventional photodiode where the absorbing zone would only be formed of a T2SL superlattice, or maintained performances but at a higher operating temperature.

Thus, for a nominal operating temperature of 130 to 140K for example, and thanks to the crystalline quality of the bulk material of the first bulk absorbing part 11.1, it appears that the photodetector 1 according to the invention makes it possible to reduce the dark current associated with the absorbing zone 11, compared to that of the conventional MWIR T2SL photodiode. Furthermore, this same bulk absorbing part 11.1, by its isotropic transport properties, makes it possible to improve the quantum efficiency QE associated with the absorbing zone 11, compared to that of the conventional MWIR T2SL photodiode. Indeed, in the case of a conventional thick T2SL, the vertical diffusion length (along the axis Z) is small, to the extent that the quantum efficiency QE rapidly degrades as soon as the thickness of the T2SL is greater than this diffusion length. Let us recall here that quantum efficiency QE is defined as the number of electron-hole pairs generated and collected per incident photon. Moreover, if it is sought to maintain identical performances to those of the conventional MWIR T2SL photodiode, in particular in terms of dark current and quantum efficiency, the photodetector 1 according to the invention can be used at a higher operating temperature, for example from 140 to 150K.

Moreover, as detailed hereinafter, the presence of the first bulk absorbing part 11.1 in the absorbing zone 11 makes it possible, in the case of a photodetector array, to improve the modulation transfer function MTF without degrading the fill factor. Let us recall here that the MTF is one of the merit functions of an infrared photodetector array, which makes it possible to quantify the incidence of large diffusion lengths from one detection pixel on a neighboring pixel. More generally, it makes it possible to measure the ability of the photodetector array to render details contained in an observed scene.

Note finally that the embodiment of the absorbing zone 11 of the photodetector 1 makes it possible to minimize the risks of the absorbing zone, once produced, not having the desired properties. Indeed, in the case of an absorbing zone formed entirely of a T2SL superlattice of several microns in thickness, there is a risk of a drift of the deposition flows used to produce the alternation of thin layers, thus degrading the properties of the superlattice, in particular when the T2SL is produced by molecular-beam epitaxy (MBE). On the other hand, in the photodetector 1, the second SL absorbing part 11.2 preferably forms not more than half the thickness of the absorbing zone. Risks of flow drift during superlattice growth are thus limited.

FIGS. 2A and 2B are schematic and partial cross-sectional views of MWIR barrier photodetectors 1 according to different embodiments. In these examples, the photodetectors 1 are arrays, in the sense that they comprise a matrix of detection pixels. In these examples, the second electrode 5 here rests in contact with the second SL absorbing part 11.2, but it could also rest in contact with the first bulk absorbing part 11.1 or the lower layer 3, or even in contact with the support substrate 2.

With reference to FIG. 2A, the photodetector array 1 has a so-called shallow-etch pixelation configuration, where only the contact layer 13 is locally etched. In addition, the barrier layer 12, as well as the underlying layers 3, 11, 12, remain continuous in the plane XY and common to all detection pixels. Thus, the contact layer 13 is etched so as to form portions 13p distinct from each other in the plane XY. It is referred to as crosslinked. A first electrode 4 rests on and in contact with each portion 13p of the contact layer 13. Each detection pixel thus has lateral dimensions in the plane XY which are defined by the periodicity pitch of the portions 13p of the contact layer 13 along the axes X and Y. A passivation layer 6 extends here on the edges of the portions 13p and on the free surface of the barrier layer 12.

However, there is still a need to improve the MTF of the photodetector array 1, and therefore reduce the effects of crosstalk between detection pixels, i.e. a photogenerated minority carrier at one detection pixel being collected by the adjacent detection pixel. Indeed, lateral diffusion of photogenerated minority carriers can be sufficient to cause crosstalk, in particular for the small detection pixel pitches, and therefore degrade the MTF.

One solution would obviously be to carry out deep pixelation etching, i.e. etching the semiconductor barrier structure 10 locally to the support substrate or at least to the lower layer 3. However, although this approach effectively results in improved MTF, it results in a degradation of the fill factor of the photodetector array. It can also result in a degradation of the quantum efficiency of each detection pixel. Furthermore, this localized deep etching is technically difficult to achieve, and can create defects at the edges, which can then be difficult to passivate and generate leaks thus degrading the dark current of the structure.

FIG. 2B illustrates an photodetector array 1 according to one embodiment, which makes it possible to improve the MTF while optimizing the fill factor and limiting passivation problems of the edges of the mesas 20 then formed.

Here, the contact layer 13, the barrier layer 12 and the second SL absorbing part 11.2 are etched locally to form detection mesas 20. They are said to be cross-linked (or discretized). Each of these layers is then formed of several portions distinct from each other. A mesa is a structure delimited in the plane XY by edges. Each mesa is therefore distinct from its neighbors in the plane XY.

On the other hand, the first bulk absorbing part 11.1 is not locally etched: it is therefore continuous in the plane XY and is common to all the detection pixels. Each detection pixel is therefore formed by a mesa 20 (portion 13p of the crosslinked contact layer 13, portion 12p of the crosslinked barrier layer 12, and portion 11.2p of the crosslinked second SL absorbing part 11.2) and by an underlying zone of the first bulk absorbing part 11.1.

This structural configuration of the photodetector array 1 effectively makes it possible to limit the degradation of the MTF. Indeed, it appears that, in the photodetector array of FIG. 2A, the degradation of the MTF is largely due to the anisotropic nature of the transport in the superlattice of the second SL absorbing part 11.2. Thus, it is particularly advantageous to only locally etch the second SL absorbing part 11.2, and not the first bulk absorbing part 11.1. This makes it possible to reduce crosstalk and therefore improves the MTF.

Note also that the valence band offset dE_{g} limits the transport of photogenerated minority holes in the second SL absorbing part 11.2 in the direction of the first bulk absorbing part 11.1, thus optimizing the MTF associated with the second SL absorbing part 11.2. Furthermore, the carriers from the first bulk absorbing part 11.1 and entering the T2SL layer 11.2 can no longer return to the first bulk absorbing part 11.1 to diffuse to the neighboring pixels within the non-crosslinked layer. The MTF associated with the first bulk absorbing part 11.1 is therefore not degraded by the presence of the second SL absorbing part 11.2.

Moreover, only locally etching the second SL absorbing part 11.2 and not the first bulk absorbing part 11.1 also makes it possible to optimize the quantum efficiency QE. Indeed, the quantum efficiency will be optimal in the first bulk absorbing part 11.1 insofar as it is not etched by pixelation, and will only be reduced in the second SL absorbing part 11.2. In addition, the evolution of the quantum efficiency QE as a function of the wavelength shows a high value in the blue band, and a lower value in the red band.

Furthermore, insofar as the second SL absorbing part 11.2 has, preferably, a thickness less than half the thickness of the absorbing zone 11, and in particular less than the first bulk absorbing part 11.1, the local etching can then be shallow. Production of the passivation layer 6 is then facilitated, and the fill factor of the second SL absorbing part 11.2 is superior. This pixelation configuration is then intermediate between the shallow-etch configuration and the deep-etch configuration. Note finally that the intermediate layer can be used as an etch stop layer during the step of producing the mesas 20 by localized etching.

Specific embodiments have just been described. Different variants and modifications will become apparent to the person skilled in the art.

1. An infrared barrier photodetector, configured to detect a light radiation of interest having a central wavelength between 3 and 5 μm, comprising
a semiconductor barrier structure based on III-Sb, resting on a support substrate based on III-Sb, the semiconductor barrier being formed of:
an absorbing zone, configured to absorb the light radiation of interest;
a barrier layer; and
a contact layer,
wherein the absorbing zone is formed of a two-part stack comprising:
a first absorbing part, doped according to a first conductivity type, made of a bulk material based on InAsSb, located on the support substrate side; and
a second absorbing part, doped according to the first conductivity type, and formed of a superlattice, located between the first absorbing part and the barrier layer.

2. The infrared photodetector according to claim 1, comprising a detection pixel array, the first absorbing part being a continuous layer common to each detection pixel.

3. The infrared photodetector according to claim 2, wherein
the contact layer is crosslinked and is formed of a plurality of portions distinct from each other,
the barrier layer is crosslinked and is formed of a plurality of portions distinct from each other,
the second absorbing part is crosslinked and is formed of a plurality of portions distinct from each other,
each detection pixel is formed of a mesa resting on the first absorbing part, and
each mesa is formed by a portion of the crosslinked contact layer, a portion of the crosslinked barrier layer, and a portion of the crosslinked second absorbing part.

4. The infrared photodetector according to claim 2, wherein the contact layer is crosslinked and is formed of a plurality of portions distinct from each other, each detection pixel being formed of a portion of the contact layer, the second absorbing part being a continuous layer common to each detection pixel.

5. The infrared photodetector according to claim 2, comprising an intermediate layer located between and in contact with the first absorbing part and the second absorbing part, the intermediate layer being a continuous layer common to each detection pixel.

6. The infrared photodetector according to claim 1, wherein the first absorbing part is based on InAsSb lattice-matched with the support substrate.

7. The infrared photodetector according to claim 1, wherein the second absorbing part is based on InAs/InAsSb, InAs/AlSb or InAs/GaSb.

8. The infrared photodetector according to claim 1, wherein the first absorbing part has a thickness greater than that of the second absorbing part.

9. The infrared photodetector according to claim 1, wherein the first absorbing part has a thickness at least equal to half that of the absorbing zone.

10. The infrared photodetector according to claim 1, wherein the semiconductor barrier structure is XBn-type, a valence band of the second absorbing part having a greater energy than that of a valence band of the first absorbing part, or the semiconductor barrier structure is XBp-type, a conduction band of the second absorbing part having a lower energy than that of a conduction band of the first absorbing part.
